(19) United States
(12) Patent Application Publication
(10) Pub. No.: US 2023/0413588 A1
(43) Pub. Date: Dec. 21, 2023

(54) OPTICAL SENSOR AND MANUFACTURING METHOD THEREOF

(71) Applicant: Japan Display Inc., Tokyo (JP)

(72) Inventor: Jun NITTA, Tokyo (JP)

(21) Appl. No.: 18/336,103

(22) Filed: Jun. 16, 2023

(30) Foreign Application Priority Data
Jun. 20, 2022 (JP) 2022-099017

(51) Int. Cl. H10K 39/32

(52) U.S. Cl. CPC H10K 39/32; G06V 40/1318

(57) ABSTRACT

An optical sensor includes: a substrate; a pixel electrode provided on the substrate; an organic photoelectric conversion layer laminated on a surface of the pixel electrode; and a common electrode laminated on a surface of the organic photoelectric conversion layer, wherein in a cross-sectional view, the surface of the pixel electrode is heightened gradually or stepwise from an end portion closest to the substrate in a direction perpendicular to the substrate toward a top portion farthest from the substrate in the direction perpendicular to the substrate, and the surface of the organic photoelectric conversion layer and a surface of the common electrode each have a shape corresponding to a shape of the surface of the pixel electrode.

### CROSS-REFERENCE TO RELATED APPLICATION

The present application claims priority from Japanese Application No. 2022-099017 filed on Jun. 20, 2022, the contents of which are hereby incorporated by reference into this application.

### BACKGROUND OF THE INVENTION

### 1. Field of the Invention

The present disclosure relates to an optical sensor and a manufacturing method thereof.

### 2. Description of the Related Art

In recent years, an optical sensor in which organic photodiodes (OPD) are arranged on a substrate has been known. Such a detection device is used as a biometric sensor for detecting biometric information, such as a fingerprint and a vein.

For example, as described in JP2021-125691A and JP2021-57422A, an optical sensor using a conventional OPD has a flat surface of a pixel electrode.

### SUMMARY OF THE INVENTION

The conventional optical sensor described above is unable to improve the sensing capability unless the plane area of the pixel electrode (the effective area of the pixel electrode in a plan view) is enlarged or the volume of the organic photoelectric conversion layer deposited on the pixel electrode is increased. That is, the sensing capability of the optical sensor using the OPD depends on a surface area of an organic photoelectric conversion layer and a common electrode on a surface of each pixel electrode and a volume of the organic photoelectric conversion layer. In a case where the surface of the pixel electrode is flat as described above, the plane area of the pixel electrode needs to be enlarged so as to enlarge the surface area of the organic photoelectric conversion layer and the common electrode disposed on the surface. However, in view of miniaturization of the device, there is a limit to the enlargement of the plane area of the pixel electrode.

One or more embodiments of the present invention have been conceived in view of the above, and an object thereof is to provide an optical sensor and a manufacturing method thereof capable of improving sensing efficiency without enlarging a plane area of a pixel electrode.

An optical sensor includes: a substrate; a pixel electrode provided on the substrate; an organic photoelectric conversion layer laminated on a surface of the pixel electrode; and a common electrode laminated on a surface of the organic photoelectric conversion layer, wherein in a cross-sectional view, the surface of the pixel electrode is heightened gradually or stepwise from an end portion closest to the substrate in a direction perpendicular to the substrate toward a top portion farthest from the substrate in the direction perpendicular to the substrate, and the surface of the organic photoelectric conversion layer and a surface of the common electrode each have a shape corresponding to a shape of the surface of the pixel electrode.

### BRIEF DESCRIPTION OF THE DRAWINGS

FIG. 1 is a schematic plan view of an optical sensor according to an embodiment of the present invention;

FIG. 2 is a block diagram showing an example of a configuration of the optical sensor according to the embodiment of the present invention;

FIG. 3 is a partial sectional view of the optical sensor taken along the line B-B of FIG. 1;

FIG. 4 is an enlarged partial sectional view of a pixel electrode and its surroundings shown in FIG. 3;

FIG. 5A is a schematic cross-sectional view of the optical sensor in the manufacturing process according to the embodiment of the present invention;

FIG. 5B is a schematic cross-sectional view of the optical sensor in the manufacturing process according to the embodiment of the present invention;

FIG. 5C is a schematic cross-sectional view of the optical sensor in the manufacturing process according to the embodiment of the present invention;

FIG. 5D is a schematic cross-sectional view of the optical sensor in the manufacturing process according to the embodiment of the present invention;

FIG. 5E is a schematic cross-sectional view of the optical sensor in the manufacturing process according to the embodiment of the present invention;

FIG. 5F is a schematic cross-sectional view of the optical sensor in the manufacturing process according to the embodiment of the present invention;

FIG. 5G is a schematic cross-sectional view of the optical sensor in the manufacturing process according to the embodiment of the present invention;

FIG. 6A is an enlarged schematic plan view of the process shown in FIG. 5A;

FIG. 6B is an enlarged schematic plan view of the process shown in FIG. 5B;

FIG. 6C is an enlarged schematic plan view of the process shown in FIG. 5C;

FIG. 6D is an enlarged schematic plan view of the process shown in FIG. 5D;

FIG. 6E is an enlarged schematic plan view of the process shown in FIG. 5E;

FIG. 6F is an enlarged schematic plan view of the process shown in FIG. 5F;

FIG. 6G is an enlarged schematic plan view of the process shown in FIG. 5G;

FIG. 7 is a partial sectional view of the optical sensor taken along the line B-B of FIG. 1 in a modification of the present embodiment;

FIG. 8 is a partial sectional view of the optical sensor taken along the line B-B of FIG. 1 in a reference example; and

FIG. 9 is a partial sectional view of the optical sensor taken along the line B-B of FIG. 1 in another reference example.

### DETAILED DESCRIPTION OF THE INVENTION

Embodiments of the present invention will be described below in detail with reference to the accompanying drawings. In this regard, the present invention is not to be limited to the embodiments described below, and can be changed as appropriate without departing from the spirit of the invention.

The accompanying drawings may schematically illustrate widths, thicknesses, shapes, or other characteristics of each part for clarity of illustration, compared to actual configurations. However, such a schematic illustration is merely an example and not intended to limit the present invention. In this specification and the drawings, some elements identical or similar to those shown previously are denoted by the same reference signs as the previously shown elements, and thus repetitive detailed descriptions of them may be omitted as appropriate.

Further, in the detailed description of the present invention, when a positional relationship between a component and another component is defined, if not otherwise stated, the words “on” and “below” suggest not only a case where the another component is disposed immediately on or below the component, but also a case where the component is disposed on or below the another component with a third component interposed therebetween.

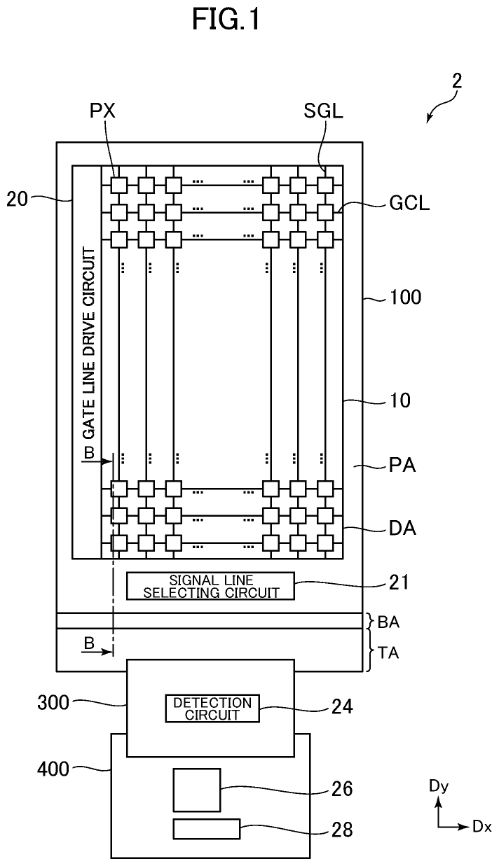

FIG. 1 is a schematic plan view of an optical sensor according to an embodiment of the present invention. As shown in FIG. 1, an optical sensor 2 includes a resin substrate 100, a sensor unit 10, a gate line drive circuit 20, a signal line selecting circuit 21, a detection circuit 24, a control circuit 26, and a power supply circuit 28.

The resin substrate 100 is electrically connected to a control substrate 400 via a flexible printed board 300. The flexible printed board 300 includes the detection circuit 24. The control substrate 400 includes the control circuit 26 and the power supply circuit 28. The control circuit 26 is a field programmable gate array (FPGA), for example. The control circuit 26 supplies control signals to the sensor unit 10, the gate line drive circuit 20, and the signal line selecting circuit 21 so as to control the detection operation of the sensor unit 10. The power supply circuit 28 supplies a power supply voltage to the sensor unit 10, the gate line drive circuit 20, and the signal line selecting circuit 21.

The resin substrate 100 includes a detection area DA and a frame area PA. The detection area DA is an area in which the sensor unit 10 is provided. The frame area PA is an area outside the detection area DA where the sensor unit 10 is not provided. In other words, the frame area PA is an area between the end portion of the detection area DA and the end portion of the resin substrate 100.

The frame area PA has a bending area BA and a terminal area TA. The bending area BA and the terminal area TA are provided at one end of the frame area. Wires connected to the detection area DA are disposed in the bending area BA and the terminal area TA. The resin substrate 100 and the flexible printed board 300 are connected to each other in the terminal area TA.

The sensor unit 10 includes a plurality of pixels PX. The pixels PX are disposed in a matrix in the detection area DA. The pixels PX are photodiodes and respectively output electric signals corresponding to light irradiating the respective photodiodes. Each pixel PX outputs an electric signal corresponding to the light irradiating the pixel PX to the signal line selecting circuit 21 as a detection signal Vdet. In the present embodiment, the optical sensor 2 detects biological data, such as a blood vessel image of a finger and a palm, a pulse wave, a pulse, and a blood-oxygen saturation, based on the detection signal Vdet from each pixel PX. Each pixel PX performs detection in accordance with a gate drive signal Vgcl supplied from the gate line drive circuit 20.

The gate line drive circuit 20 and the signal line selecting circuit 21 are provided in the frame area PA. Specifically, the gate line drive circuit 20 is provided in an area of the frame area PA that extends along the extending direction (second direction Dy) of a signal line SGL. The signal line selecting circuit 21 is provided in an area of the frame area PA that extends along the extending direction (first direction Dx) of a gate line GCL and provided between the sensor unit 10 and the bending area BA.

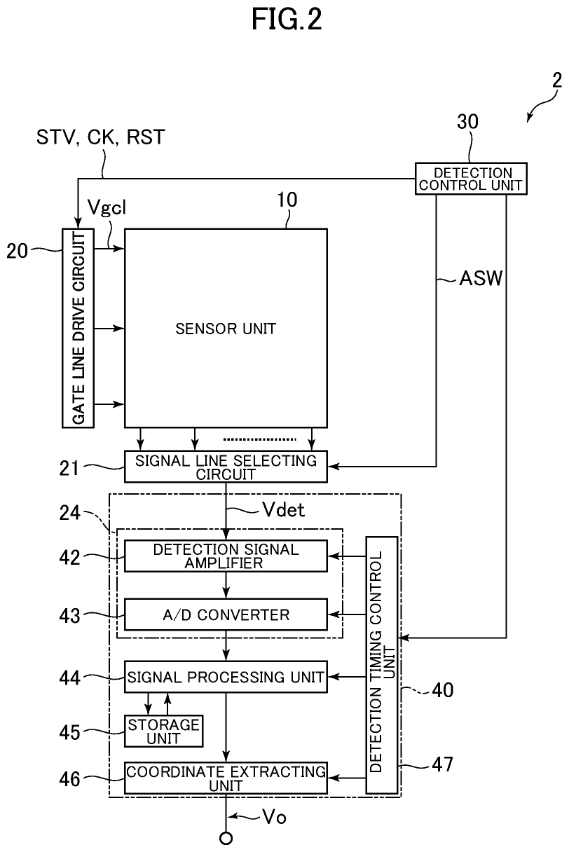

FIG. 2 is a block diagram showing an example of a configuration of the optical sensor according to the embodiment of the present invention. As shown in FIG. 2, the optical sensor 2 further includes a detection control unit 30 and a detection unit 40. Some or all of the functions of the detection control unit 30 are included in the control circuit 26. Further, some or all of the functions of the detection unit 40 other than the detection circuit 24 are included in the control circuit 26.

The detection control unit 30 is a circuit that supplies control signals to the gate line drive circuit 20, the signal line selecting circuit 21, and the detection unit 40, and controls these operations. The detection control unit 30 supplies control signals, such as a start signal STV, a clock signal CK, and a reset signal RST, to the gate line drive circuit 20. The detection control unit 30 supplies control signals, such as a selection signal ASW, to the signal line selecting circuit 21.

The gate line drive circuit 20 drives the gate line GCL based on the control signals. The gate line drive circuit 20 sequentially or simultaneously selects a plurality of gate lines GCL, and supplies a gate drive signal Vgcl to the selected gate line GCL. In this manner, the gate line drive circuit 20 selects a pixel PX connected to the gate line GCL.

The signal line selecting circuit 21 is a switching circuit that sequentially or simultaneously selects a plurality of signal lines SGL. The signal line selecting circuit 21 is a multiplexer, for example. The signal line selecting circuit 21 connects the selected signal line SGL with the detection circuit 24 based on the selection signal ASW supplied from the detection control unit 30. This enables the signal line selecting circuit 21 to output a detection signal Vdet of the pixel PX to the detection unit 40.

The detection unit 40 includes the detection circuit 24, a signal processing unit 44, a storage unit 45, a coordinate extracting unit 46, and a detection timing control unit 47. The detection timing control unit 47 controls the detection circuit 24, the signal processing unit 44, and the coordinate extracting unit 46 to operate in synchronization based on the control signal supplied from the detection control unit 30.

The detection circuit 24 is an analog front end (AFE) circuit, for example. The detection circuit 24 is a signal processing circuit having at least functions of a detection signal amplifier 42 and an A/D converter 43. The detection signal amplifier 42 amplifies the detection signal Vdet. The A/D converter 43 converts an analog signal from the detected signal amplifier 42 into a digital signal.

The signal processing unit 44 is a logic circuit that detects a predetermined physical quantity entered into the sensor unit 10 based on the output signal of the detection circuit 24. When a detection target, such as a finger and a palm, comes into contact with or is close to the detection surface, the signal processing unit 44 detects unevenness of the surface of the finger and the palm based on the signal from the detection circuit 24. Further, the signal processing unit 44 detects biological data, such as a blood vessel image of a finger and a palm, a pulse wave, a pulse, and a blood-oxygen saturation, based on a signal from the detection circuit 24.

The storage unit 45 temporarily stores the signal calculated by the signal processing unit 44. The storage unit 45 may be a random access memory (RAM) or a register circuit, for example.

The coordinate extracting unit 46 is a logic circuit that obtains detection coordinates of unevenness of a surface of a finger and a palm, for example, when the signal processing unit 44 detects contact or approach of the finger or the palm. The coordinate extracting unit 46 is a logic circuit that obtains detection coordinates of blood vessels of a finger and a palm, for example. The coordinate extracting unit 46 combines detection signals Vdet from the respective pixels PX of the sensor unit 10 to generate two-dimensional information indicating the shape of the unevenness of the surface of the finger and the palm, for example. The coordinate extracting unit 46 may not calculate the detection coordinates but output the detection signal Vdet as the sensor output Vo.

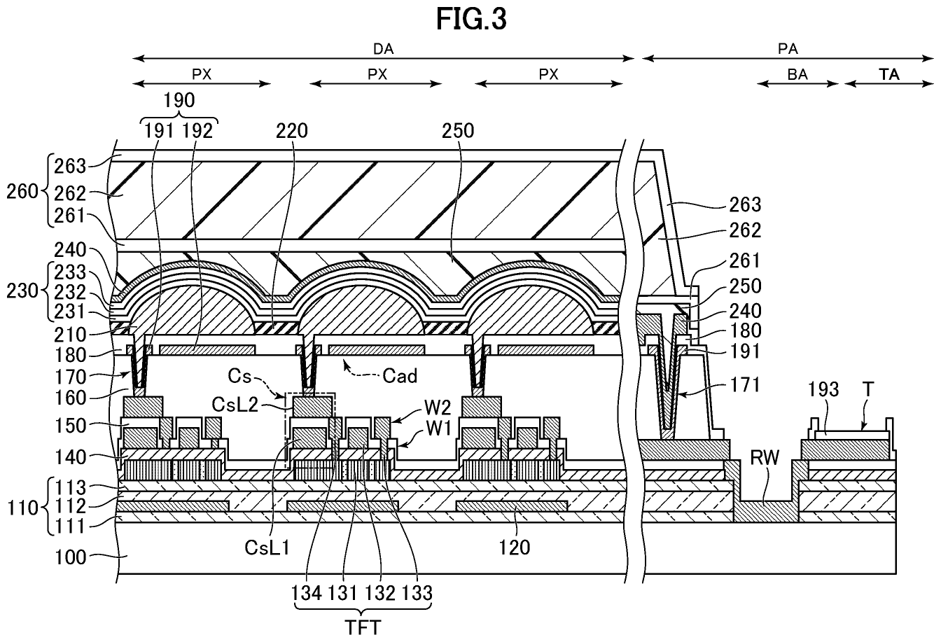

FIG. 3 is a partial sectional view of the optical sensor 2 taken along the line B-B of FIG. 1. In FIG. 3, a part of the detection area DA and a part of the frame area PA are shown in a cross-sectional view. As described above, the detection area DA includes a plurality of pixels PX, and the frame area PA includes the bending area BA and the terminal area TA. Each pixel PX includes a corresponding one of the pixel electrodes 210 and a corresponding one of the thin film transistors TFT.

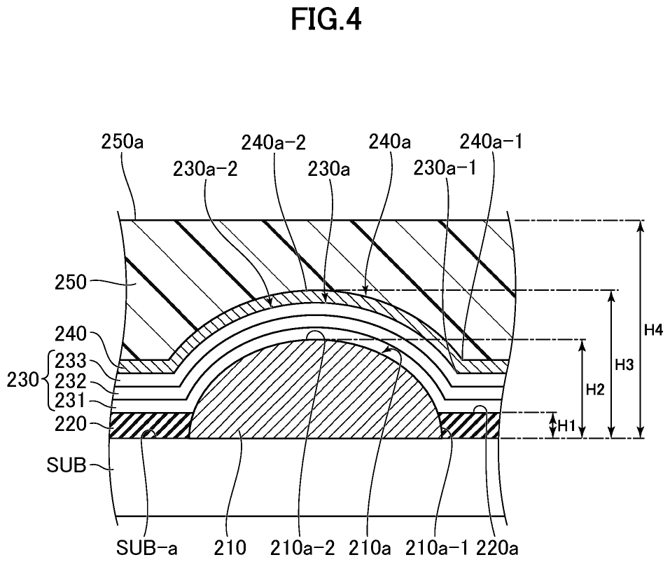

FIG. 3 shows the cut surface in the second direction Dy. When the detection area DA is cut in the first direction Dx, the same cross-sectional configuration as in FIG. 4 is observed. In FIG. 3, hatching of some layers is omitted for clarity of the cross-sectional structure (the same applies to FIGS. 4 to 9). In the following, the cross-sectional structure shown in FIG. 3 will be described in order from the lower layer.

A barrier inorganic film 110 is laminated on the resin substrate 100. The resin substrate 100 is made of polyimide. However, any resin material may be used if the substrate has sufficient flexibility as the sheet-type optical detection device. The barrier inorganic film 110 has a three-layered structure of a first inorganic film (e.g., silicon oxide film) 111, a second inorganic film (e.g., silicon nitride film) 112, and a third inorganic film (e.g., silicon oxide film) 113. The first inorganic film 111 is provided to improve the adhesion to the substrate, the second inorganic film 112 is provided to block moisture and impurities from the outside, and the third inorganic film 113 is provided to prevent hydrogen atoms contained in the second inorganic film 112 from diffusing to the semiconductor layer 131, but the structure is not particularly limited thereto. The structure may include an additional layer, or may be formed of one layer or two layers.

An additional film 120 may be formed at a portion where the thin film transistor TFT to be described later is formed. The additional film 120 prevents a change in characteristics of the thin film transistor TFT due to penetration of light from the back surface of the channel of the thin film transistor TFT or provides a predetermined potential by being formed of a conductive material, thereby providing a back gate effect to the thin film transistor TR. Here, after the first inorganic film 111 is formed, the additional film 120 is formed in an island shape in accordance with the portion where the thin film transistor TFT is formed, and then the second inorganic film 112 and the third inorganic film 113 are laminated, so that the additional film 120 is sealed in the barrier inorganic film 110. In this regard, the present invention is not limited thereto, and the additional film 120 may be formed on the resin substrate 100 and then the barrier inorganic film 110 may be formed.

A thin film transistor TFT is formed on the barrier inorganic film 110 for each pixel PX. The thin film transistor TFT includes a semiconductor layer 131, a gate electrode 132, a source electrode 133, and a drain electrode 134. Here, a polysilicon thin film transistor is taken as an example, and only an N-channel transistor is shown, although a P-channel transistor may be simultaneously formed. The semiconductor layer 131 of the thin film transistor TFT has a structure in which a low-concentration impurity region or an intrinsic semiconductor region is provided between a channel region and a source/drain region. The gate electrode 132 is a portion where the gate line GCL is electrically connected to the semiconductor layer 131 in each pixel PX. Similarly, the source electrode 133 is a portion where the signal line SGL is electrically connected to the semiconductor layer 131 in each pixel PX.

A gate insulating film 140 is provided between the semiconductor layer 131 and the gate electrode 132. Here, a silicon oxide film is used as the gate insulating film 140. The gate electrode 132 is a part of the first wiring layer W1 formed of MoW. The first wiring layer W1 includes a first holding capacitance line CsL1 in addition to the gate electrode 132. A part of the holding capacitor Cs is formed between the first holding capacitance line CsL1 and the semiconductor layer 131 (source/drain regions) via the gate insulating film 140.

An interlayer insulating film 150 is formed on the gate electrode 132. The interlayer insulating film 150 has a structure in which a silicon nitride film and a silicon oxide film are laminated. The films from the barrier inorganic film 110 to the interlayer insulating film 150 are patterned and removed at the area corresponding to the bending area BA. The polyimide forming the resin substrate 100 is exposed in the area corresponding to the bending area BA. When the barrier inorganic film 110 is patterned to be removed, the surface of the polyimide may be partially eroded or lost.

A wiring pattern is formed under each of the step at the edge of the interlayer insulating film 150 and the step at the edge of the barrier inorganic film 110. A routing wire RW to be formed in the next process is disposed over the wiring pattern when crossing the steps. For example, the gate electrode 132 is disposed between the interlayer insulating film 150 and the barrier inorganic film 110, and the additional film 120 is disposed between the barrier inorganic film 110 and the resin substrate 100. As such, the wiring pattern is formed using these layers.

A second wiring layer W2, which includes the source electrode 133, the drain electrode 134, and a portion serving as the routing wire RW, is formed on the interlayer insulating film 150. Here, a three-layered structure of Ti, Al, and Ti is employed. The first holding capacitance line CsL1 (a part of the first wiring layer W1) and the second holding capacitance line CsL2 (a part of the second wiring layer W2) form another part of the holding capacitor Cs via the interlayer insulating film 150. The routing wire RW extends to the terminal area TA via the bending area BA and forms a terminal portion T to which the flexible printed substrate 300 is connected, for example.

The routing wire RW is formed so as to reach the terminal portion T across the bending area BA, and thus crosses the steps of the interlayer insulating film 150 and the barrier inorganic film 110. As described above, the wiring pattern formed by the additional film 120, for example, is formed in the steps. As such, even if the routing wire RW is disconnected at the recess of the step, the electrical connection can be maintained by contacting the wiring pattern.

A flattening film 160 is disposed so as to cover the source electrode 133, the drain electrode 134, and the interlayer insulating film 150. The flattening film 160 is made of resin, such as photosensitive acryl, because such a material is superior in surface flatness to an inorganic insulating material formed by CVD (chemical vapor deposition), for example. The flattening film 160 is removed in a pixel contact portion 170, a common electrode contact portion 171, the bending area BA, and the terminal area TA.

A transparent conductive film 190 made of indium tin oxide (ITO) is formed on each pixel PX on the flattening film 160. The transparent conductive film 190 includes a first transparent conductive film 191 and a second transparent conductive film 192, which are separated from each other.

In the pixel contact portion 170, the first transparent conductive film 191 covers the second wiring layer W2, a surface of which is exposed by removal of the flattening film 160. An inorganic insulating film (silicon nitride film) 180 is provided on the flattening film 160 so as to cover the first transparent conductive film 191. The inorganic insulating film 180 is open to the pixel contact portion 170.

The second transparent conductive film 192 is disposed below a pixel electrode 210 to be described later (further below the inorganic insulating film 180) and next to the pixel contact portion 170. The second transparent conductive film 192, the inorganic insulating film 36, and the pixel electrode 210 overlap one another and form an additional capacitance Cad.

A third transparent conductive film 193 may be formed on the surface of the terminal portion T. The third transparent conductive film 193 formed on the surface of the terminal portion T may be provided for the purposes of protecting the exposed wiring portion from a damage in a subsequent process.

The laminated structure from the resin substrate 100 to the inorganic insulating film 180 (hereinafter referred to as a substrate SUB) has been discussed. In the following, the structure of the layers above the substrate SUB will be described with reference to FIGS. 3 and 4. FIG. 4 is an enlarged partial sectional view of the pixel electrode and its surroundings shown in FIG. 3.

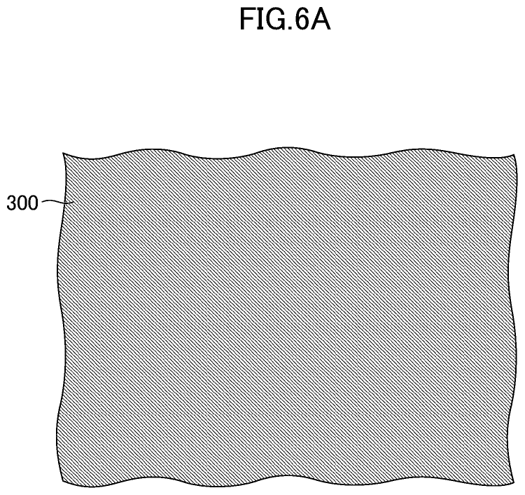

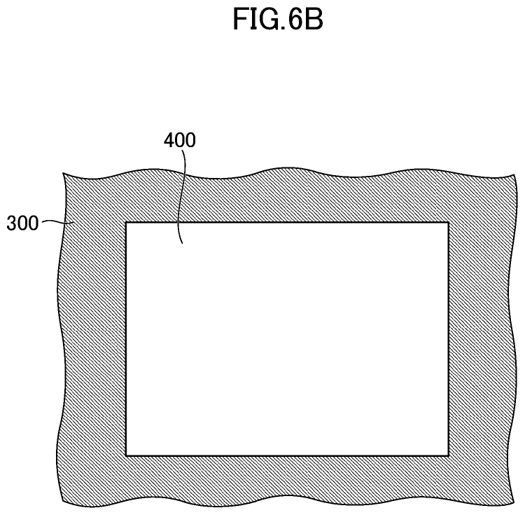

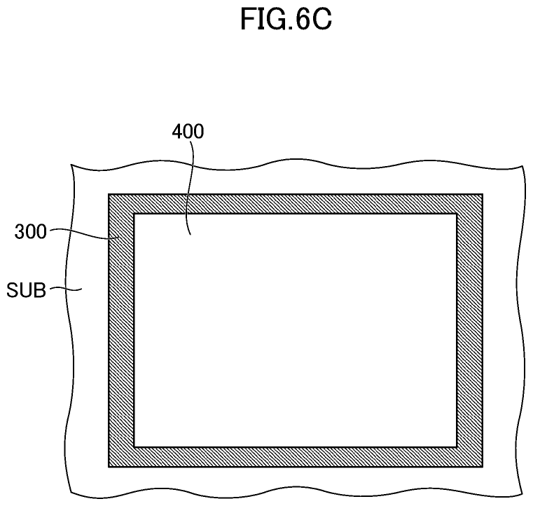

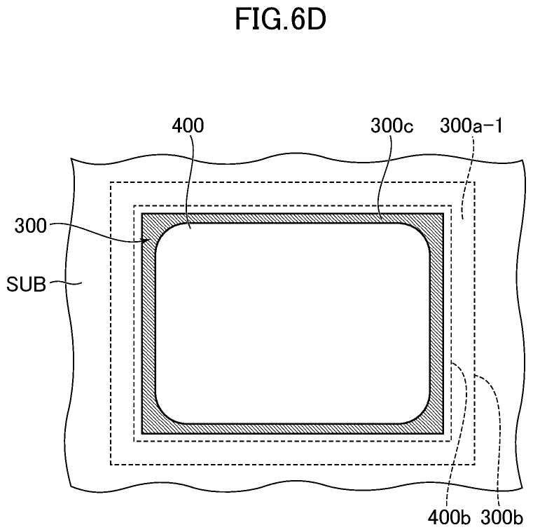

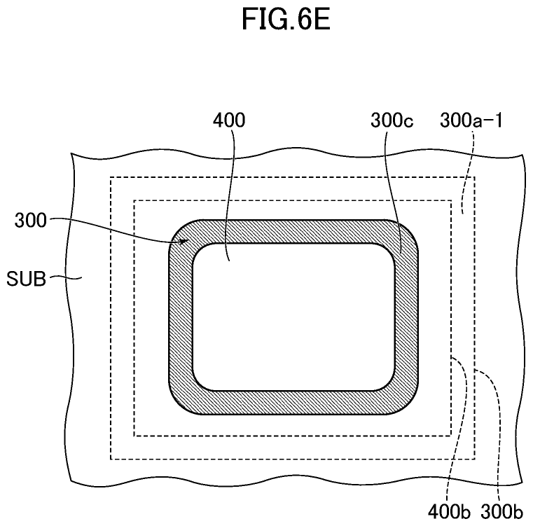

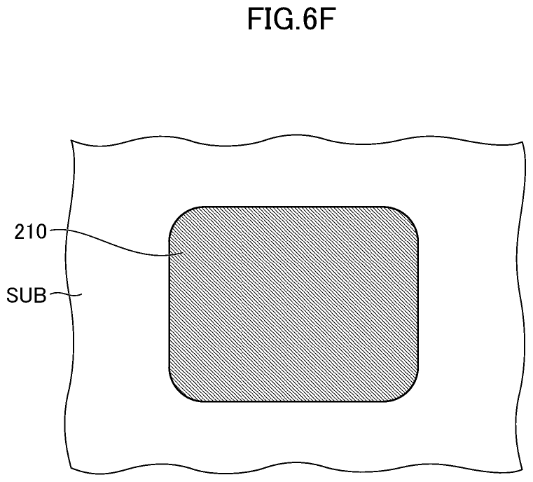

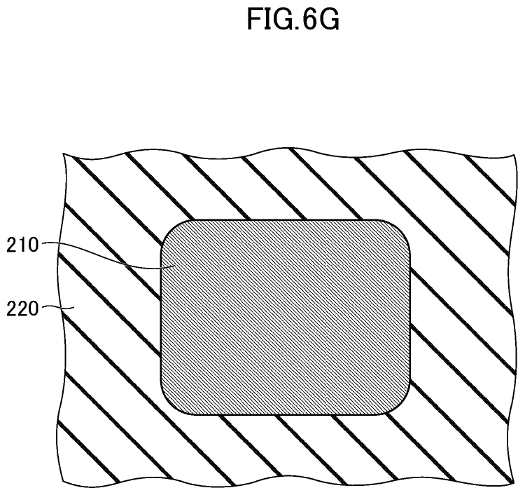

A plurality of pixel electrodes 210 adjacent to each other are provided on the substrate SUB (more specifically, the inorganic insulating film 180). Specifically, the pixel electrodes 210 are respectively provided for the pixels PX so as to be electrically connected to the drain electrode 134 through the opening of the inorganic insulating film 180 in the pixel contact portion 170. The pixel electrode 210 is formed as a reflective electrode and has a three-layered structure of an indium zinc oxide film, an Ag film, and an indium zinc oxide film. An indium tin oxide film may be used instead of the indium zinc oxide film. The pixel electrode 210 extends laterally from the pixel contact portion 170 and above the thin film transistor TFT. As will be described later, the pixel electrode 210 has a square shape in a plan view (see FIGS. 6G and 6G).

In a cross-sectional view, a surface 210a of the pixel electrode 210 is gradually heightened from an end portion 210a-1, which is closest to the substrate SUB in the direction perpendicular to the substrate SUB, toward a top portion 210a-2, which is farthest from the substrate SUB in the direction perpendicular to the substrate. More specifically, the end portion 210a-1 is a portion of the surface 210a of the pixel electrode 210 where the surface SUB-a of the substrate SUB is in contact with the surface 210a of the pixel electrode 210. The top portion 210a-2 is the farthest portion of the surface 210a of the pixel electrode 210 from the surface SUB-a of the substrate SUB in a direction perpendicular to the substrate SUB.

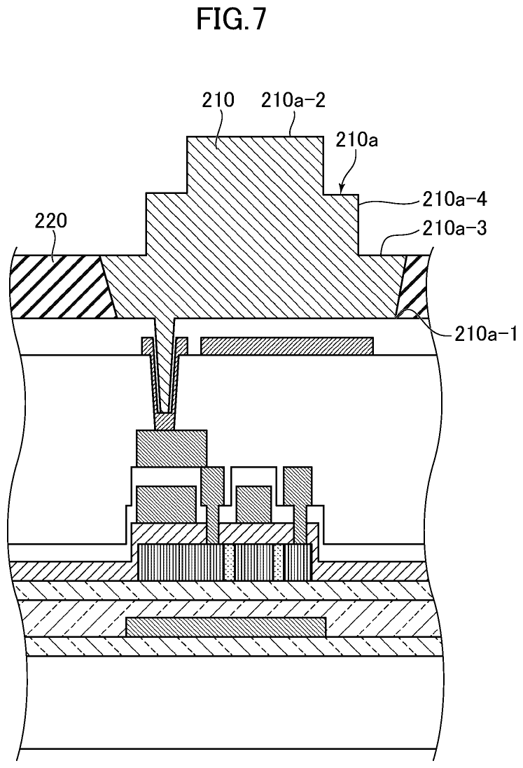

In other words, distances from the surface 210a of the pixel electrode 210 to the substrate SUB in the direction perpendicular to the substrate SUB gradually increase from the end portion 210a-1 toward the top portion 210a-2. As will be described later, the distances may increase stepwise from the end portion 210a-1 toward the top portion 210a-2 (see FIG. 7). Alternatively, the surface 210a of the pixel electrode may have both of a portion where the distances gradually increase from the end portion 210a-1 toward the top portion 210a-2 and a portion where the distances increase stepwise from the end portion 210a-1 toward the top portion 210a-2.

In the present embodiment, the pixel electrode 210 has a curved shape in a cross-sectional view. Such a structure is less likely to cause coverage defects when an organic photoelectric conversion layer 230 to be described later is formed on the surface 210a of the pixel electrode 210.

An insulating layer 220 having a plurality of openings respectively corresponding to the pixel electrodes 210 is provided on the substrate SUB (more specifically, the inorganic insulating film 180). The insulating layer 220 is made of photosensitive acrylic, for example, similarly to the flattening film 160. The insulating layer 220 covers a part of the surface 210a (at least the end portion 210a-1) of the pixel electrode 210. In the present embodiment, the end portion of the insulating layer 220 is reversely tapered, which is due to the convenience of the manufacturing process described later.

The organic photoelectric conversion layer 230 is commonly laminated on the plurality of pixel electrodes 210 for the plurality of pixels PX (i.e., the plurality of pixel electrodes 210). That is, the organic photoelectric conversion layer 230 is provided over the entire detection area DA. The organic photoelectric conversion layer 230 is also disposed on the insulating layer 220. Specifically, the organic photoelectric conversion layer 230 is disposed on a surface 210a of each of the pixel electrodes 210 and the surface 220a of the insulating layer 220.

The organic photoelectric conversion layer 230 includes a lower charge transport layer 231, an active layer 232, and an upper charge transport layer 233. More specifically, the organic photoelectric conversion layer 230 has a structure in which the lower charge transport layer 231, the active layer 232, and the upper charge transport layer 233 are laminated in this order from the bottom. The active layer 232 converts light incident on the optical sensor 2 into electric charges. The lower charge transport layer 231 and the upper charge transport layer 233 transport the electric charges generated in the active layer 232. In a case where the surface irradiation type structure is employed, the lower charge transport layer 231 is a hole-transport layer and the upper charge transport layer 233 is an electron transport layer, and in a case where the back surface irradiation type structure is employed, the lower charge transport layer 231 is an electron transport layer and the upper charge transport layer 233 is a hole transport layer.

The common electrode 240 is commonly laminated on the organic photoelectric conversion layer 230 commonly for the plurality of pixels PX (i.e. the plurality of pixel electrodes 210). That is, the common electrode 240 is disposed over the entire detection area DA similarly to the organic photoelectric conversion layer 230. In a case where the surface irradiation type structure is employed, the upper electrode 240 needs to be transparent. Specifically, PEDOT:PSS is formed on the surface in contact with the organic photoelectric conversion layers 230, and the common electrode 240 is then formed using a metallic material, such as Ag and Al, as a thin film through which the incident light is transmitted. The common electrode 240 is formed over the organic photoelectric conversion layer 230 provided in the detection area DA and the common electrode contact portion 171 provided in the frame area PA. In the common electrode contact portion 171, the second wiring layer W2 is electrically connected to the routing wire RW and eventually extracted to the terminal portion T.

The organic photoelectric conversion layer 230 and the common electrode 240 are formed to have a uniform or substantially uniform thickness. As such, the surface 230a of the organic photoelectric conversion layer 230 and the surface 240a of the common electrode 240 each have a shape corresponding to the shape of the surface 210a of the pixel electrode 210. That is, the surface 230a of the organic photoelectric conversion layer 230 is gradually heightened from an end portion 230a-1, which is closest to the substrate SUB in the direction perpendicular to the substrate SUB, toward a top portion 230a-2, which is farthest from the substrate SUB in the direction perpendicular to the substrate. Similarly, the surface 240a of the pixel electrode 240 is gradually heightened from an end portion 240a-1, which is closest to the substrate SUB in the direction perpendicular to the substrate SUB, toward a top portion 240a-2, which is farthest from the substrate SUB in the direction perpendicular to the substrate. More specifically, in a cross-sectional view, the surface 230a of the organic photoelectric conversion layer 230 and the surface 240a of the common electrode 240 are curved.

According to the above structure, the surface area of the organic photoelectric conversion layer 230 and the common electrode 240 laminated on the surface 210a of the pixel electrode 210 can be increased without enlarging the plane area of the pixel electrode 210. As such, the sensing efficiency of the optical sensor 2 can be improved regardless of the size of the plane area of the pixel electrode 210. Here, the “plane area” refers to an effective area of the pixel electrode 210 in a plan view. More specifically, the “plane area” is an area of the surface 210a of the pixel electrode 210 that is not covered with the insulating layer 220 (i.e., an area overlapping the opening of the insulating layer 220) in a plan view.

In a cross-sectional view, the top portion 210a-2 of the pixel electrode 210 is farther from the substrate SUB than the surface 220a of the insulating layer 220 in the direction perpendicular to the substrate SUB. In other words, in a cross-sectional view, a distance H1 between the surface 220a of the insulating layer 220 and a surface SUB-a of the substrate SUB in the direction perpendicular to the substrate SUB is smaller than a distance H2 between the top portion 210a-2 of the pixel electrode 210 and the surface SUB-a of the substrate SUB in the direction perpendicular to the substrate SUB. According to the above structure, the surface area of the organic photoelectric conversion layer layers 230 and the common electrode 240 laminated on the surface 210a of the pixel electrode 210 can be more reliably increased.

A flattening layer 250 is laminated on the common electrode 240. More specifically, the flattening layer 250 is laminated on the surface 240a of the common electrode 240. The surface 250a of the flattening layer 250 is flat. The distance H3 between the top portion 240a-2 of the common electrode 240 and the surface SUB-a of the substrate SUB in the direction perpendicular to the substrate SUB is smaller than the distance H4 between a surface 250a of the flattening layer 250 and the surface SUB-a of the substrate SUB in the direction perpendicular to the substrate SUB. With such a structure, the surface 240a of the common electrode 240, which protrudes upward in accordance with the surface 210a of the pixel electrode 210, is not contact with a sealing layer 260 to be described later, and thus the durability of the optical sensor 2 is improved. Similarly to the flattening film 160, materials for forming the flattening layer 260 include a resin, such as photosensitive acrylic.

The sealing layer 260 is laminated on the flattening layer 250. One of the functions of the sealing film 260 is protecting the organic photoelectric conversion layer 230 from moisture entering from the outside, and is required to have a high gas barrier property.

The sealing layer 260 includes a first inorganic material layer 261, a resin layer 262, and a second inorganic material layer 263 in this order from the bottom. More specifically, the sealing layer 260 has a structure in which the first inorganic material layer 261, the resin layer 262, and the second inorganic material layer 263 are laminated in this order from the bottom to the top. In the present embodiment, the first inorganic material layer 261 is a silicon nitride film, the resin layer 262 is an acrylic resin, and the second inorganic material layer 263 is a silicon nitride film. A silicon oxide film or an amorphous silicon layer may be provided between the first inorganic material layer 261 and the resin layer 262 for the purpose of improving the adhesion. In the present embodiment, the sealing layer 260 is provided on the light-receiving surface side, and thus, it is preferable that the materials do not absorb or otherwise act on light of the wavelength to be detected.

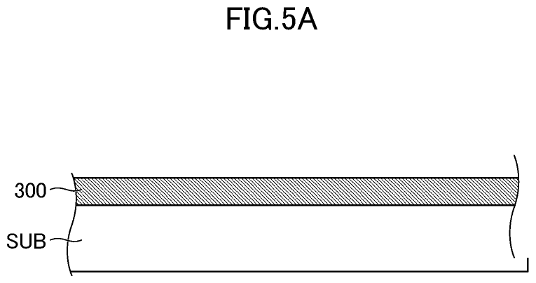

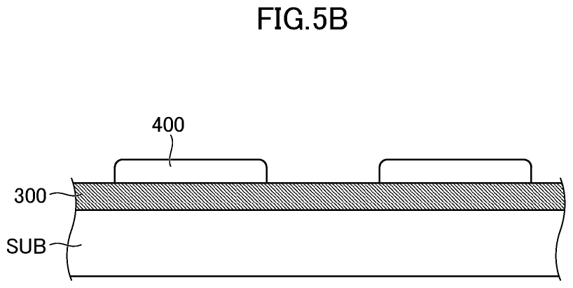

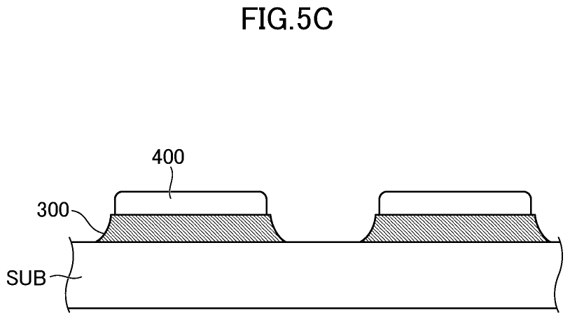

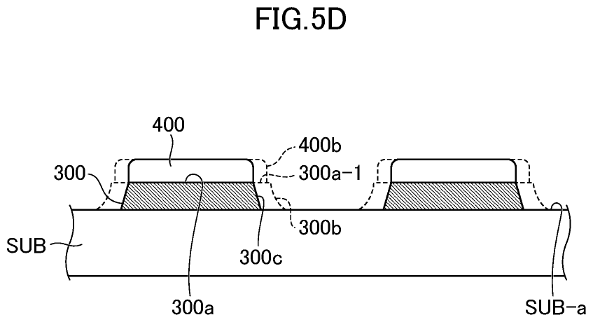

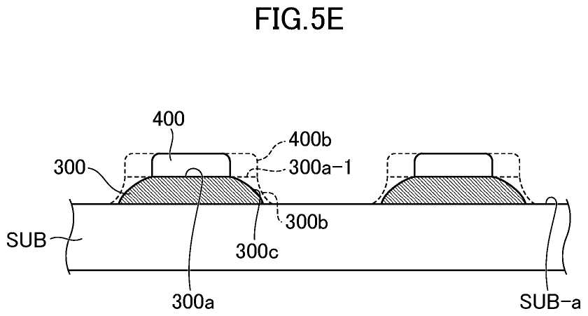

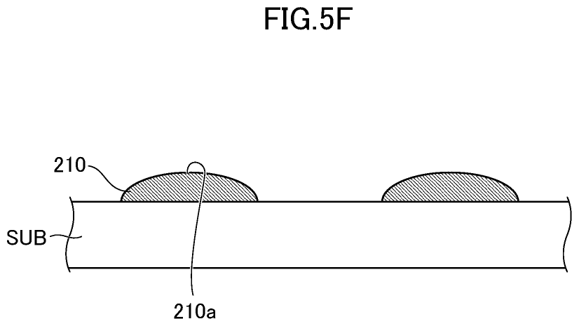

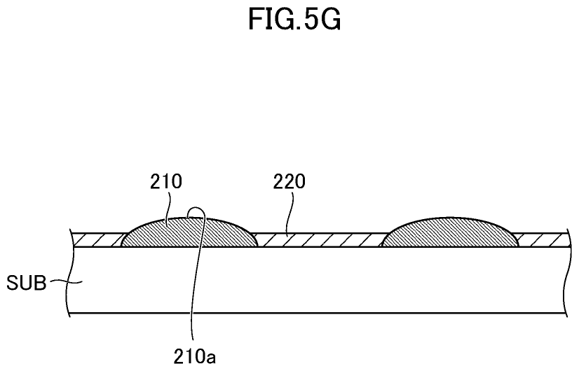

In the following, referring to FIGS. 5 (5A to 5G) and 6 (6A to 6G), the manufacturing process of the optical sensor 2 shown in FIGS. 3 and 4 will be described. FIG. 5 is a schematic cross-sectional view of the optical sensor in the manufacturing process according to the embodiment of the present invention. FIG. 6 is a schematic diagram of the process shown in FIG. 5 in a plan view.

First, a first conductive film 300 is formed on the substrate SUB (FIGS. 5A and 6A). The first conductive film 300 is processed in a later step to form a pixel electrode 210. Next, a plurality of resist films 400 are formed on the first conductive film 300 (FIGS. 5B and 6B). Specifically, the plurality of resist films 400 are formed at positions corresponding to positions where the plurality of pixel electrodes 210 are formed in a subsequent process.

Subsequently, the first conductive film 300 is etched (FIGS. 5C and 6C). Specifically, the first conductive film 300 is dry-etched using the resist film 400 as an etching mask, and a portion of the first conductive film 300 where the resist film 400 is not formed is selectively removed.

Next, the resist film 400 and the first conductive film 300 are simultaneously etched (FIGS. 5E to 5E and FIGS. 6D to 6E). At this time, in a cross-sectional view, the first conductive film 300 is processed such that the surface of the first conductive film 300 is gradually heightened from the end portion, which is closest to the substrate SUB in the direction perpendicular to the substrate SUB, toward the top portion, which is farthest from the substrate SUB in the direction perpendicular to the substrate SUB.

Specifically, in the processes shown in FIGS. 5D and 6D, a side portion 400b of the resist film 400 indicated by a broken line is etched to be retracted (to be moved toward the center of the resist film 400). As the side portion 400b of the resist film 400 is retracted, an upper surface 300a of the first conductive film 300 is gradually exposed. In this process, the side portion 300b of the first conductive film 300 indicated by the broken line and an exposed portion 300a-1 of the upper surface 300a of the first conductive film 300 indicated by the broken line are simultaneously etched. Subsequently, as shown in FIGS. 5E and 6E, in a cross-sectional view, the taper angle of the surface 300c (a portion not covered with the resist film 400) of the first conductive film 300 decreases as being away from the surface SUB-a of the substrate SUB in the direction perpendicular to the substrate SUB. Here, the “taper angle” refers to an angle formed by a tangent line at one point of the surface 300c of the first conductive film 300 and the surface SUB-a of the substrate SUB in a cross-sectional view.

After the etching is completed, the resist film 400 is removed (FIGS. 5F and 6F). As described above, the first conductive film 300 remaining after the resist film 400 is removed is used as the pixel electrode 210. As shown in FIG. 5F, the surface 210a of the pixel electrode 210 is curved in a cross-sectional view due to the processes shown in FIGS. 5D to 5E and 6D to 6E.

Subsequently, an insulating layer 220 (insulating film) is formed on the substrate SUB (see FIGS. 5G and 6G). At this time, the insulating layer 220 is formed such that the top portion of the pixel electrode 210 is farther from the substrate SUB than the surface of the insulating layer 220 in a cross-sectional view in a direction perpendicular to the substrate SUB (see FIG. 4). An organic photoelectric conversion layer 230 (organic photoelectric conversion film) is formed on the pixel electrode 210 and the insulating film 220, and a common electrode 240 (second conductive film) is formed on the organic photoelectric conversion film (not shown). At this time, the organic photoelectric conversion layer 230 is formed such that the surface of the organic photoelectric conversion layer 230 has a shape corresponding to the shape of the surface 210a of the pixel electrode 210 (see FIG. 4). Further, the common electrode 240 is formed such that the surface of the common electrode 240 has a shape corresponding to the shape of the surface 210a of the pixel electrode 210 (see FIG. 4). Details of the insulating layer 220, the organic photoelectric conversion layer 230, and the common electrode 240 are as described above, and thus the description thereof will be omitted.

As shown in FIGS. 6F and 6G, the pixel electrode 210 is square in a plan view. This secures better sensing efficiency and resolution as compared with a case where the pixel electrode 210 has a circular shape in a plan view.

A modification of the present invention will be described. FIG. 7 is a partial sectional view of the optical sensor 2 taken along the line B-B of FIG. 1 according to the first modification.

In a cross-sectional view, a surface 210a of the pixel electrode is heightened stepwise from an end portion 210a-1, which is closest to the substrate SUB in the direction perpendicular to the substrate SUB, toward a top portion 210a-2, which is farthest from the substrate SUB in the direction perpendicular to the substrate. In the present modification as well, the surface 210a of the pixel electrode may have both of a portion where the distances gradually increase from the end portion 210a-1 toward the top portion 210a-2 and a portion where the distances increase stepwise from the end portion 210a-1 toward the top portion 210a-2.

That is, in the present modification, the surface 210a of the pixel electrode 210 is shaped like a step. Specifically, the surface 210a of the pixel electrode 210 shown in FIG. 7 includes a plurality of top surfaces 210a-3 and a plurality of stepped surfaces 210a-4 respectively rising from the corresponding top surfaces 210a-3 other than the uppermost surface (in this case, the same surface as the top portion 210a-2). FIG. 7 shows three steps formed by the upper surfaces 210a-3 and the stepped surfaces 210a-4, although the number of steps may be two or four or more.

The pixel electrode 210 shown in FIG. 7 can be formed by a simpler process than the pixel electrode 210 shown in FIGS. 3 and 4. For example, the pixel electrode 210 having the structure shown in FIG. 7 can be formed by disposing a plurality of metal masks having different sizes of openings.

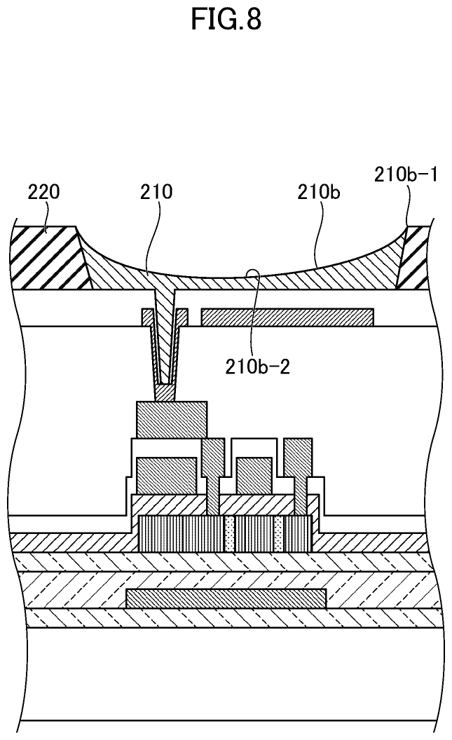

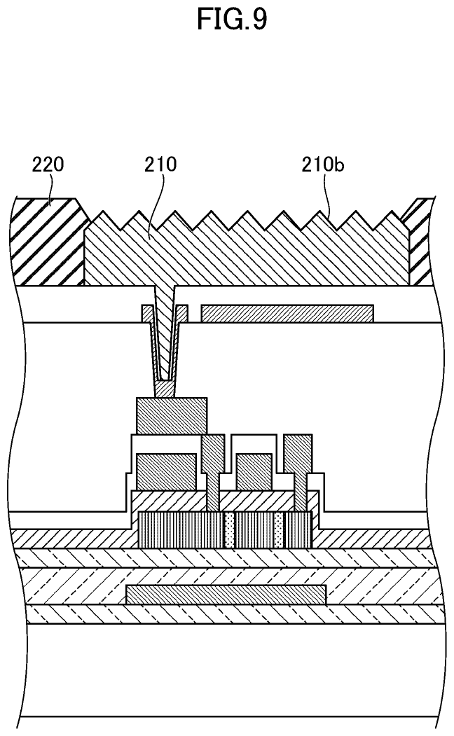

According to the optical sensor of the present invention described above, the surface area of the organic photoelectric conversion layer and the common electrode laminated on the surface of the pixel electrode can be increased without enlarging the plane area of the pixel electrode. As such, the sensing efficiency of the optical sensor can be improved regardless of the size of the plane area of the pixel electrode. Specifically, in the examples shown in FIGS. 3, 4, and 7, there are fewer portions where the cross section of the pixel electrode is narrow as compared with examples shown in FIGS. 8 and 9 to be described later, and thus it is possible to prevent locally high resistance from occurring.

In the following, reference examples will be described with reference to FIGS. 8 and 9.

FIG. 8 is a partial sectional view of the optical sensor 2 taken along the line B-B of FIG. 1 in the reference example. The upper surface 210b of the pixel electrode 210 shown in FIG. 8 is gradually lowered from an edge portion 210b-1 toward a bottom portion 210b-2. For example, the pixel electrode 210 having the structure shown in FIG. 8 can be formed by forming an insulating layer 220 having a forward tapered end and then disposing a film in an opening portion of the insulating layer 220. With this structure as well, the sensing efficiency of the optical sensor 2 can be improved regardless of the size of the plane area of the pixel electrode 210. Specifically, the shape of the pixel electrode 210 shown in FIG. 8 has an advantage in terms of light collection. The upper surface 210b of the pixel electrode 210 may be gradually lowered from the edge portion 210b-1 toward the bottom portion 210b-2. The upper surface 210b of the pixel electrode 210 may have both a portion that is gradually lowered from the edge portion 210b-1 toward the bottom portion 210b-2 and a portion that is lowered stepwise from the edge portion 210b-1 toward the bottom portion 210b-2.

FIG. 9 is a partial sectional view of the optical sensor 2 taken along the line B-B of FIG. 1 in another reference example. The upper surface 210b of the pixel electrode 210 shown in FIG. 9 has an uneven shape. Such an uneven shape of the upper surface 210b can be obtained by forming the pixel electrodes 210 and then roughening the upper surface 210b by a vacuum process, such as sputtering. With this structure as well, the sensing efficiency of the optical sensor 2 can be improved regardless of the size of the plane area of the pixel electrode 210. Specifically, the shape of the pixel electrode 210 shown in FIG. 9 has an advantage in terms of improving the surface area.

In the example shown in FIG. 9, the surface of the flattening film 160 may have an uneven shape, and the pixel electrode 210 may be formed thereon by a vacuum process, such as sputtering, so as to form an uneven shape of the upper surface 210b of the pixel electrode 210. This manufacturing method is applicable not only to the example shown in FIG. 9 but also to the examples shown in FIGS. 3, 4, 7, and 8. When the pixel electrode 210 is formed in this manner, the pixel electrode 210 can be processed into a desired shape by a simpler process.

In the examples shown in FIGS. 3, 4, 7, and 8, the insulating layer 220 is provided so as not to overlap with the pixel contact portion 170 in a plan view, although the insulating layer 220 may be provided so as to overlap with the pixel contact portion 170 in a plan view. That is, when the shape of the pixel electrode 210 is processed by the manufacturing method described above, short-circuiting or disconnection of the organic photoelectric conversion layer 230 in the upper layer of the pixel electrode 210 may occur in the pixel contact portion 170. In this regard, such short-circuiting or disconnection can be prevented by the insulating layer 220 disposed so as to overlap with the pixel contact portion 170 in a plan view.

The present invention is not limited to the above embodiment, and various modifications can be made. For example, a replacement can be made with a configuration that is substantially the same as the configuration shown in the above-described embodiment, a configuration that exhibits the same operational effect, or a configuration that can achieve the same object.

Within the scope of the idea of the present invention, those skilled in the art can come up with various changes and modifications and it will be understood that these changes and modifications also fall into the scope of the present invention. For example, in each of the above-described embodiments, addition, deletion or redesign of a component, or addition, omission or condition change of a process, which are appropriately made by a person skilled in the art, are also included within the scope of the present invention as long as they remain the gist of the present invention.

1. An optical sensor comprising:
a substrate;
a pixel electrode provided on the substrate;
an organic photoelectric conversion layer laminated on a surface of the pixel electrode; and
a common electrode laminated on a surface of the organic photoelectric conversion layer, wherein
in a cross-sectional view, the surface of the pixel electrode is heightened gradually or stepwise from an end portion closest to the substrate in a direction perpendicular to the substrate toward a top portion farthest from the substrate in the direction perpendicular to the substrate, and
the surface of the organic photoelectric conversion layer and a surface of the common electrode each have a shape corresponding to a shape of the surface of the pixel electrode.

2. The optical sensor according to claim 1, wherein
the surface of the pixel electrode is curved in a cross-sectional view.

3. The optical sensor according to claim 1, wherein
the pixel electrode is square in a plan view.

4. The optical sensor according to claim 1, further comprising an insulating layer that is provided on the substrate and includes an opening corresponding to the pixel electrode, wherein
the organic photoelectric conversion layer is laminated on a surface of the insulating layer, and
in a cross-sectional view, the top portion of the pixel electrode is farther from the substrate than the surface of the insulating layer in a direction perpendicular to the substrate.

5. The optical sensor according to claim 1, further comprising a flattening layer that is laminated on the surface of the common electrode and has a flat surface.

6. A method for manufacturing an optical sensor comprising:
a first conductive film forming step of forming a first conductive film on a substrate;
a resist film forming step of forming a resist film on the first conductive film;
a first conductive film etching step of etching the first conductive film;
a simultaneously etching step of simultaneously etching the resist film and the first conductive film;
a resist film removing step of removing the resist film;
an organic photoelectric conversion film forming step of forming an organic photoelectric conversion film on the first conductive film; and
a second conductive film forming step of forming a second conductive film on the organic photoelectric conversion film, wherein
in the simultaneously etching step, the first conductive film is processed such that, in a cross-sectional view, the surface of the first conductive film is heightened gradually or stepwise from an end portion closest to the substrate in a direction perpendicular to the substrate toward a top portion farthest from the substrate in the direction perpendicular to the substrate,
in the organic photoelectric conversion film forming step, the organic photoelectric conversion film is formed such that a surface of the organic photoelectric conversion film has a shape corresponding to a shape of the surface of the first conductive film, and
in the second conductive film forming step, the second conductive film is formed such that a surface of the second conductive film has a shape corresponding to a shape of the surface of the first conductive film.

7. The method according to claim 6 further comprising, between the resist film removing step and the organic photoelectric conversion film forming step, an insulating film forming step of forming an insulating film on the substrate, the insulating film including an opening corresponding to the pixel electrode in a plan view, wherein
in the organic photoelectric conversion film forming step, the organic photoelectric conversion film is formed on the insulating film, and
in the insulating film forming step, the insulating film is formed such that the top portion of the first conductive film is farther from the substrate than a surface of the insulating film in a direction perpendicular to the substrate in a cross-sectional view.
